(19) United States
(12) Patent Application Publication
(10) Pub. No.: US 2024/0221550 A1
(43) Pub. Date: Jul. 4, 2024

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Haoran Sun, Wuhan, Hubei (CN); Qipei Zhang, Wuhan, Hubei (CN); Xiuyan Li, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/758,213

(22) PCT Filed: Jun. 9, 2022
(86) PCT No.: PCT/CN2022/097802

§ 371 Date: Nov. 2, 2023

(30) Foreign Application Priority Data
Apr. 28, 2022 (CN) 202210463604.4

(51) Int. Cl. G09G 3/00; G01R 31/56; G09G 3/3225; H10K 59/131; H10K 59/80

(52) U.S. Cl. CPC G09G 3/006; G01R 31/56; G09G 3/3225; H10K 59/131; G09G 2300/0842; H10K 59/873

(57) ABSTRACT

The present application provides a display panel and a display device. The display panel includes a crack blocking area defined adjacent to and surrounding the accommodating hole; wherein the ring-shaped detection trace is configured to provide signals to at least one of the rows or the columns of pixel driving circuits. When a crack occurs at the accommodating hole in the display area, the crack will first impact the ring-shaped detection trace, causing abnormal display of the pixel unit, which can reduce the difficulty of crack detection.

### BACKGROUND OF INVENTION

### Field of Invention

The present application is related to the field of display technology, and in particular, relates to a display panel and a display device.

### Description of Prior Art

With the development of full-screen display devices such as mobile phones, how to hide a front camera has become an urgent problem to be solved. In the related art, the camera is usually hidden by drilling holes in the display area of the display panel for accommodation of the camera.

During a production process of a display panel, positions of the drilling holes on the display panel is prone to cracks. Since the signal line is also set at the drilling positions, cracks at the drilling positions are likely to cause the breakage of the signal line in the display panel, thereby causing the abnormal display phenomenon. If this abnormal display phenomenon is not detected in time in the subsequent process, it will impact a factory pass rate of the display panel.

### SUMMARY OF INVENTION

Embodiments of the present application provide a touch display panel and a touch display device, so as to improve the dark streak phenomenon that occurs after the touch display panel is subjected to a reliability test.

In a first aspect, an embodiment of the present application provides a display panel, including:
a display area provided with an accommodating hole;
a pixel unit disposed in the display area, wherein the pixel unit includes pixel driving circuits arranged in rows and columns;
a crack blocking area defined adjacent to and surrounding the accommodating hole;
a ring-shaped detection trace disposed in the crack blocking area; wherein the ring-shaped detection trace has a ring shape and surrounds the accommodating hole, and the ring-shaped detection trace is configured to provide a signal to at least one of the rows or the columns of the pixel driving circuits.

In a second aspect, an embodiment of the present application provides a display device, including a controller, a camera unit, and a display panel, wherein the camera unit is installed in an accommodating hole of the display panel, and the controller is connected to the camera unit and the display panel; and

wherein the display panel includes:
a display area provided with the accommodating hole;
a pixel unit disposed in the display area, wherein the pixel unit includes pixel driving circuits arranged in rows and columns;
a crack blocking area defined adjacent to and surrounding the accommodating hole;
a ring-shaped detection trace disposed in the crack blocking area; wherein the ring-shaped detection trace has a ring shape and surrounds the accommodating hole, and the ring-shaped detection trace is configured to provide a signal to at least one of the rows or the columns of the pixel driving circuits.

In the display panel provided by the embodiment of the present application, the ring-shaped detection trace is arranged in the crack blocking area closest to the accommodating hole, and the ring-shaped detection trace is connected to at least one of the rows or the columns of pixel driving circuits. In this way, when a crack occurs at the accommodating hole in the display area, the crack will first impact the ring-shaped detection trace, so that the ring-shaped detection trace is broken, resulting in abnormal display of the pixel unit. That is, the inspector only needs to observe whether the pixel unit in the row or column connected to the ring-shaped detection trace is displayed normally or not, to determine whether the crack at the accommodating hole impacts the function of the display panel, thereby reducing the difficulty of crack detection.

### BRIEF DESCRIPTION OF DRAWINGS

FIG. 1 is a schematic plan view of a display panel according to an embodiment of the present application.

FIG. 2 is a schematic plan view of a display panel according to another embodiment of the present application.

FIG. 3 is a schematic plan view of a display panel according to yet another embodiment of the present application.

FIG. 4 is a schematic plan view of a ring-shaped detection trace according to an embodiment of the present application.

FIG. 5 is a schematic plan view of a ring-shaped detection trace in another embodiment of the present application.

FIG. 6 is a schematic cross-sectional view of a display panel according to an embodiment of the present application.

FIG. 7 is a schematic cross-sectional view of a crack blocking dam in an embodiment of the present application.

### DETAILED DESCRIPTION OF PREFERRED EMBODIMENTS

The technical solutions in the embodiments of the present application will be clearly and completely described below. Obviously, the described embodiments are only a part of the embodiments of the present application, but not all of the embodiments. Based on the embodiments in the present application, all other embodiments obtained by a person of ordinary skill in the art without creative efforts shall fall within the protection scope of the present application.

Embodiments of the present application provide a display panel 100 and a display device, so as to detect whether the display panel 100 malfunctions due to cracks formed by hole opening. It will be described below with reference to the accompanying drawings.

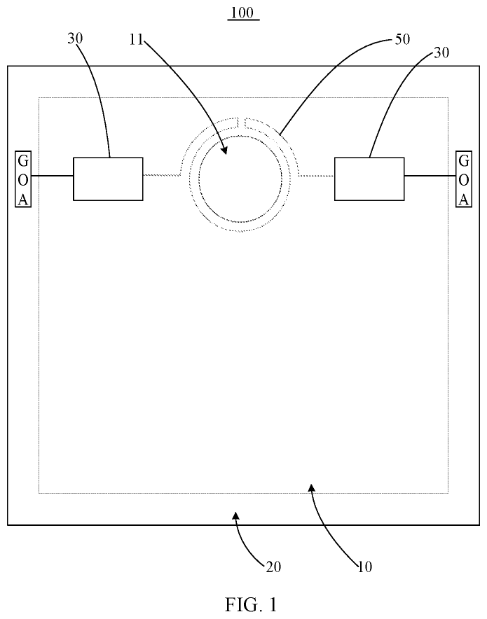

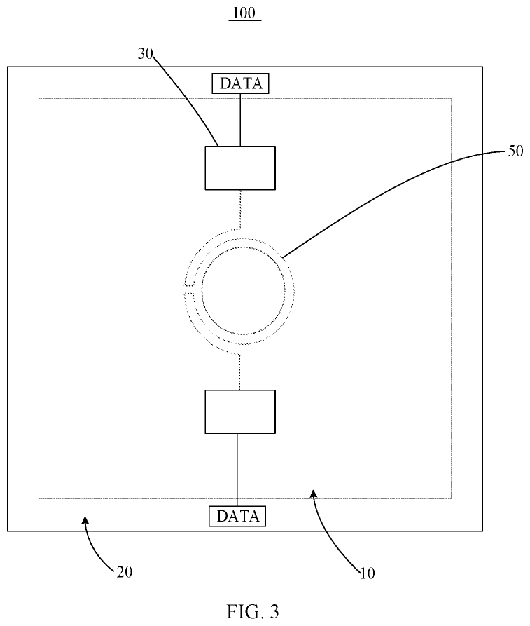

The display panel 100 provided by the embodiments of the present application can be applied to a display device. Referring to FIGS. 1 and 3, FIG. 1 is a schematic plan view of a display panel 100 provided by an embodiment of the present application; FIG. 3 is a schematic plan view of a display panel 100 provided by another embodiment of the present application. The display panel 100 includes: a display area 10, wherein the display area 10 is provided with an accommodating hole 11; a pixel unit 30 disposed in the display area 10, wherein the pixel unit 30 includes pixel driving circuits arranged in rows and columns; a crack blocking area defined adjacent to and surrounding the accommodating hole 11; a ring-shaped detection trace 50 arranged in the crack blocking area, wherein the ring-shaped detection trace 50 has a ring shape and surrounds the accommodating hole 11, and the ring-shaped detection trace 50 is configured to provide a signal to at least one of the rows or the columns of the pixel driving circuits.

In this embodiment, the display panel 100 may include a flexible substrate, a thin film transistor layer, an organic light-emitting layer, a thin film encapsulation layer, a touch layer, a color filter layer, and a glass cover sequentially from bottom to top. The thin film transistor layer includes a plurality of thin film transistors disposed on the flexible substrate, a planarization organic layer covering the thin film transistors, an anode layer on the planarization organic layer, and a pixel definition layer on the anode layer. Each thin film transistor includes an active layer, a gate insulating layer, a gate electrode, an interlayer insulating layer, and a source/drain layer which are sequentially stacked from bottom to top. The drain electrode and the source electrode of the thin film transistor are located on the source/drain electrode layer.

The display area 10 refers to an area of the display panel 100 where the pixel units 30 are arranged. Contrasted with the display area 10 is the non-display area 20 The non-display area 20 refers to an area around the display area 10. The non-display area 20 is usually used to set gate driving circuits, detection circuits, signal traces, etc. of the display panel 100. The accommodating hole 11 is used for accommodating the camera, and the accommodating hole 11 can be a through hole or a blind hole; the accommodating hole 11 can have a shape of a circle, an ellipse, a polygon, or a polygon with at least one curved side, which is not particularly limited herein. Taking the accommodating hole 11 being a blind hole as an example, the accommodating hole 11 penetrates the touch layer, the thin film encapsulation layer, the organic light-emitting layer, and the thin film transistor layer from top to bottom. Inorganic layers in these functional layers are prone to cracks after drilling at positions adjacent to the accommodating hole 11.

The pixel unit 30 is represented as a red pixel, a green pixel, and a blue pixel on the color filter layer; the pixel unit 30 is represented as a pixel driving circuits on the thin film transistor layer; and the specific type of the pixel driving circuits is not particularly limited, for example, and the pixel driving circuits can be 7T1C circuits. The number of pixel units 30 is plural, and the plurality of pixel units 30 are distributed in the display area 10, and each pixel unit 30 corresponds to a pixel driving circuit, that is, the plurality of pixel driving circuits are distributed in the display area 10 in rows and columns. The pixel driving circuits are connected to the GOA circuits and the data signal circuits on the display panel 100. The GOA circuits can provide scan signals and emission signals to the pixel driving circuits, and the data signal circuits can provide data signals to the pixel driving circuits. Usually, one scan signal line or EM signal line controls one row of pixel driving circuits, and one data signal line controls one column of pixel driving circuits. The accommodating hole 11 is located between adjacent ones of the pixel driving circuits, and the pixel driving circuits on both sides of the accommodating hole 11 may be located in the same row or in the same column, which are not particularly limited herein.

The crack blocking area is used to prevent the crack at the accommodating hole 11 from extending to other positions in the display area 10, so as to prevent the circuits on the display area 10 from breaking. The crack blocking area also has an anti-static function to prevent the circuit near the accommodating hole 11 from being broken down by static electricity. Since the crack blocking area is used to prevent the crack from extending, the crack blocking area should be set at the position closest to the accommodating hole 11.

The ring-shaped detection trace 50 is arranged in the crack blocking area, so as to effectively utilize a location advantage of the crack blocking area, so that the ring-shaped detection trace 50 can be preferentially impacted by the crack. Since cracks may occur at various positions in a circumferential direction of the accommodating hole 11, the ring-shaped detection trace 50 should extend along the circumferential direction of the accommodating hole 11 to improve the reliability of crack detection. It should be noted that the extension shape of the ring-shaped detection trace 50 in the circumferential direction of the accommodating hole 11 should be continuous, non-circulating and non-intersecting, that is, when the current flows along the circumferential direction of the accommodating hole 11 along the ring-shaped detection trace 50, there is always only one flow path, thus preventing a short circuit in the ring-shaped detection trace 50.

The ring-shaped detection trace 50 can affect one row of pixel units 30 by being connected to one of the GOA circuits, or can affect one of the pixel units 30 by being connected to one of the data signal lines.

For example, the display panel 100 further includes scan signal lines, EM signal lines, and data signal lines provided in the display area 10, the data signal lines crisscross the scan signal lines, the EM signal lines are arranged in parallel with the scan signal lines; the data signal lines, the scan signal lines, and the EM signal lines are all connected to the pixel driving circuits; the ring-shaped detection trace is connected in series to at least one of the data signal lines, the scan signal lines, or the EM signal lines.

The scan signal line and the EM signal line belong to different signal units in the GOA circuits. The scan signal line is used to provide a scan signal. The scan signal is mainly used to turn on the thin film transistors of the pixel units 30 in the row for a certain period of time, so as to input data signals to the pixel units 30 in the row to the capacitors in the pixel driving circuits in the row for storage. The scan signal or its shift signal can also be used to initialize the potential of the capacitor, or to initialize the anode of the OLED. The EM signal line is used to provide an EM signal, that is, an emission signal or a light-emitting signal; the EM signal is used to read in the data signal correctly when the scan signal turns on the thin film transistor on the pixel of the row, and to prohibit the OLED from emitting light during the processes of reading in the data and the initialization.

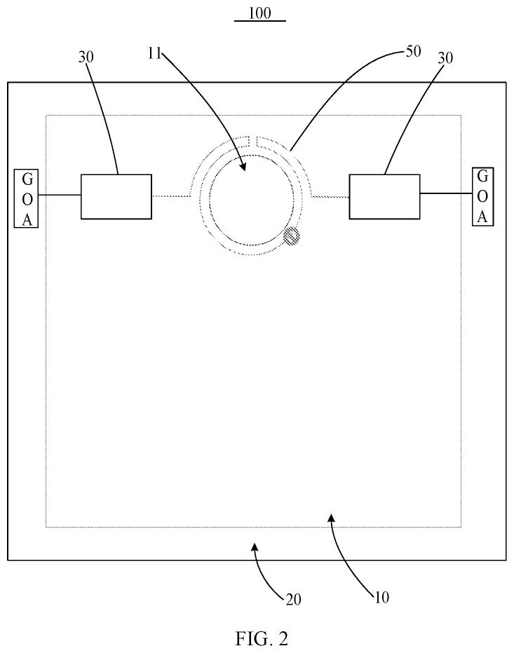

The ring-shaped detection trace 50 can be connected to the adjacent scan signal line or EM signal line to control the pixel unit 30 in the same row. Referring to FIG. 2, FIG. 2 is a schematic plan view of a display panel 100 according to another embodiment of the present application. If there is a crack at the accommodating hole 11, the ring-shaped detection trace 50 will be impacted first to result in open circuit, so that the scan signal line or EM signal line connected with the ring-shaped detection trace 50 cannot transmit the signal to the pixel driving circuits in the same column as the accommodating hole 11, resulting in abnormal display of the pixel units 30 in the row.

As shown in FIG. 3, both ends of the ring-shaped detection trace 50 may also be connected to adjacent data signal lines to control the pixel units 30 in the same column. If a crack occurs in the accommodating hole 11, the ring-shaped detection trace 50 will be impacted firstly to result in open circuit, so that the data signal line connected to the ring-shaped detection trace 50 cannot normally transmit the signal to the pixel driving circuits in the same column as the accommodating hole 11, and the pixel units 30 of the column display abnormally.

Therefore, the inspector only needs to focus on observing the display condition of the corresponding pixel unit 30 to determine the condition of the crack at the accommodating hole 11, thereby simplifying the detection process of the crack without introducing other detection circuits, so as to improve the detection efficiency and reduce the detection cost.

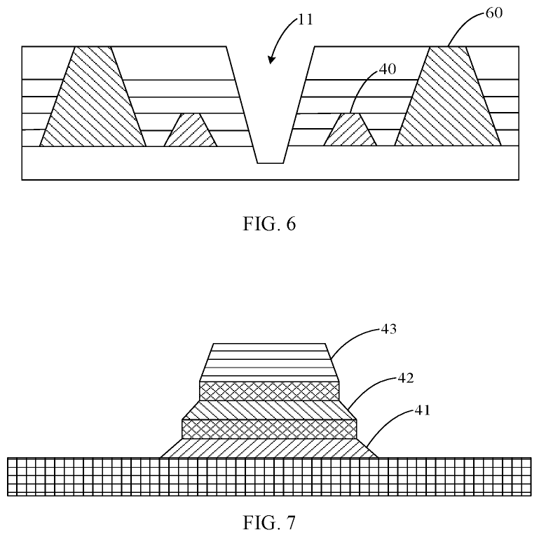

Exemplarily, referring to FIG. 6, FIG. 6 is a schematic cross-sectional view of the display panel 100 according to an embodiment of the present application. The crack blocking area is provided with a crack blocking dam 40, and the crack blocking dam 40 can not only play the role of blocking crack extension, but also play the role of anti-static. The crack blocking dam 40 has a conductive layer, and the ring-shaped detection trace 50 may be integrally formed with the conductive layer, or may be of a different structure from the conductive layer. Specifically, the ring-shaped detection trace 50 is formed by the conductive layer, so that the conductive layer of the crack blocking dam 40 can be used to directly form a pattern of the ring-shaped detection trace 50. In this way, the formation of the ring-shaped detection trace 50 can be simplified, thereby reducing process costs.

Exemplarily, the crack blocking dam 40 may be formed by stacking a plurality of conductive layers, and an insulating layer is provided between adjacent ones of the conductive layers. For example, referring to FIG. 7, FIG. 7 is a schematic cross-sectional view of the crack blocking dam 40 in an embodiment of the present application. The crack barrier dam 40 includes a first metal layer 41, a second metal layer 42, and a composite metal layer 43 arranged in sequence; an insulating layer is provided between the first metal layer 41 and the second metal layer 42, and between the second metal layer 42 and the composite metal layer 43; and the ring-shaped detection trace 50 is formed by one of the first metal layer 41, the second metal layer 42, or the composite metal layer 43.

The first metal layer 41, the second metal layer 42, and the composite metal layer 43 are all conductive layers in the crack blocking dam 40, and the ring-shaped detection trace 50 can be formed by one of them to form a ring-shaped trace pattern. Each of the first metal layer 41 and the second metal layer 42 may include one of molybdenum, silver, titanium, copper, aluminum, or alloys thereof, and the composite metal layer 43 may include titanium/aluminum/titanium; so that not only the conductivity of the conductive layer as the ring-shaped detection trace 50 can be improved, but also the blocking ability of the crack blocking dam 40 against cracks is strengthened.

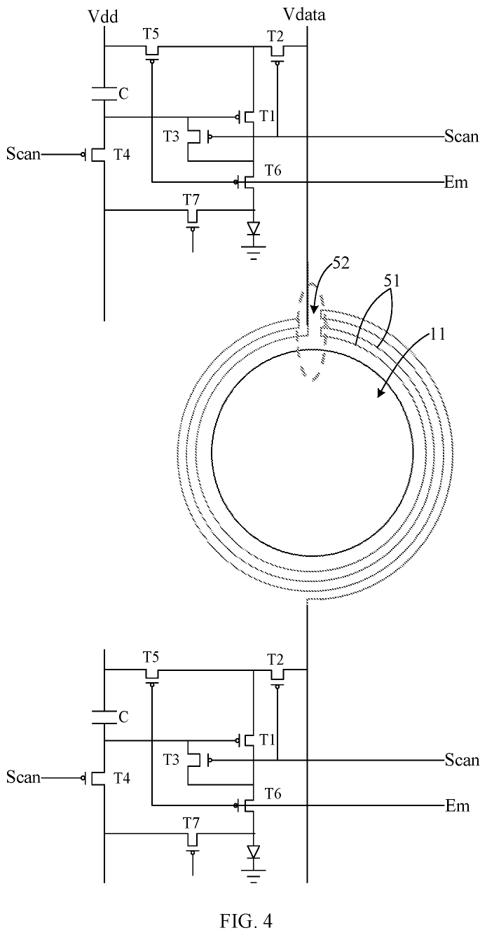

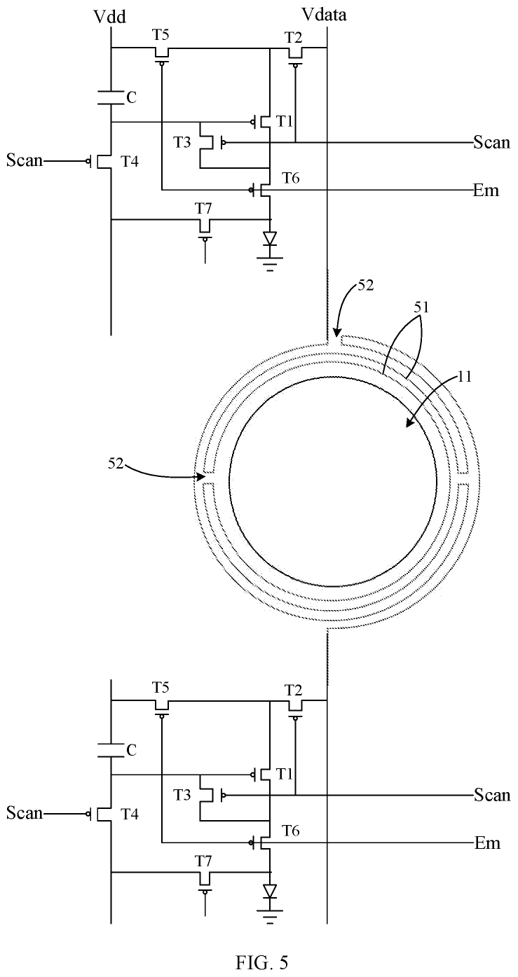

The ring-shaped detection trace 50 may be wound around the accommodating hole 11 to form only one detection coil 51, or may be wound around to form a plurality of detection coils 51. For example, referring to FIG. 4 and FIG. 5, FIG. 4 is a schematic plan view of the ring-shaped detection trace 50 in the embodiment of the present application, and FIG. 5 is a schematic plan view of a ring-shaped detection trace 50 in another embodiment of the present application. The ring-shaped detection trace 50 surrounds the accommodating hole 11 and forms a plurality of detection coils 51, and each of the detection coils 51 is non-closed, and adjacent ones of the detection coils 51 are connected in series. A plurality of detection coils 51 are arranged at intervals along a radial direction of the accommodating hole 11, and each detection coil 51 is coaxial with the accommodating hole 11. Each detection coil 51 is non-closed, that is, each detection coil 51 has at least one opening, so as to prevent the ring-shaped detection trace 50 from open circuit. Adjacent ones of the detection coils 51 are connected to each other at the opening, so that adjacent ones of the detection coils 51 are connected in series, so that every two of the plurality of detection coils 51 are connected in series. The ring-shaped detection trace 50 is wound around to form a plurality of detection coils 51 to prevent discontinuous cracks from being not detected by avoiding a single detection coil 51, thereby improving the reliability of the ring-shaped detection trace 50.

Exemplarily, as shown in FIG. 5, non-closed positions 52 of at least two of the detection coils 51 are staggered from each other in a radial direction of the accommodating hole 11; that is, the openings of the plurality of detection coils 51 are not all in the same diameter, to avoid the crack extending along this diameter and dodging all the detection coils 51 (as shown in FIG. 4); thus, the detection reliability of the crack can be further ensured. Specifically, a distance between adjacent ones of the detection coils 51 along this diameter is set to be 4 μm to 8 μm, such as 5 μm, 6 μm or 7 μm, etc., so as to prevent accidental short circuits of adjacent ones of the detection coils 51 and reasonably control a space occupied by the ring-shaped detection trace 50.

Exemplarily, as shown in FIG. 6, the display panel 100 further includes an encapsulation liquid blocking area defined in the display area 10, the encapsulation liquid blocking area is defined to surround the accommodating hole 11, and the encapsulation liquid blocking area is radially defined at a side of the crack blocking area away from the accommodating hole; the encapsulating liquid blocking area is provided with an encapsulating liquid blocking dam 60, and a size of the encapsulating liquid blocking dam 60 in a direction perpendicular to the display panel 100 is larger than a size of the crack blocking dam 40 in the direction perpendicular to the display panel 100. The encapsulation liquid blocking dam 60 is configured to block the outflow of the encapsulation liquid of the display panel 100 from the accommodating hole 11, so as to improve the structural stability of the display panel 100.

Exemplarily, the display panel 100 further includes a frame-shaped detection trace (not shown), the frame-shaped detection trace extends along an edge of the display panel 100, and the frame-shaped detection trace is configured to provide signals to at least one of the rows or the columns of the pixel driving circuits. Similar to the principle of the ring-shaped detection trace 50, the frame-shaped detection trace can detect whether a crack occurs at the edge of the display panel 100.

The frame-shaped detection trace is arranged in the thin film transistor layer, and the frame-shaped detection trace is a metal trace with a conductive function. The frame-shaped detection trace can be connected to one of the GOA circuits to affect one of the rows of pixel units 30, or to one of the columns of pixel units 30 by being connected to one of the data signal lines. Since cracks may occur at various positions along the edge of the display panel 100, the frame-shaped detection traces should extend along the edge of the display panel 100 to improve the reliability of crack detection. It should be noted that the extension shape of the frame-shaped detection trace at the edge of the display panel 100 should be continuous, non-circulating, and non-intersecting, that is, when the current flows along the frame-shaped detection trace through the edge of the display panel 100, there is always only one flow path, thereby preventing the frame detection trace from short circuit.

The frame-shaped detection traces can be connected to adjacent scan signal lines or EM signal lines to control the pixel units 30 connected to the scan signal lines or EM signal lines. If a crack occurs at the edge of the display panel 100, the frame-shaped detection traces will be impacted first to result in open circuit, so that the scan signal lines or EM signal lines connected to the frame-shaped detection traces cannot transmit signals to the corresponding pixel driving circuits normally, causing the pixel units 30 in this row to display abnormally.

The frame-shaped detection traces can also be connected to adjacent data signal lines to control a column of pixel units 30 connected to the data signal lines. If a crack occurs at the edge of the display panel 100, the frame-shaped detection traces will be impacted first to result in open circuit, so that the data signal lines connected to the frame-shaped detection traces cannot transmit signals to the corresponding pixel driving circuits normally, causing the row of pixel units 30 to display abnormality. Therefore, the inspector only needs to focus on observing the display condition of the corresponding pixel unit 30 to determine the condition of cracks at the edge of the display panel 100, thereby simplifying the detection process for cracks without introducing other detection circuits to improve detection efficiency and reduce detection cost.

Exemplarily, an embodiment of the present application further provides a display device, including a controller, a camera unit, and the above-mentioned display panel 100; the camera unit is installed in the accommodating hole 11 of the display panel 100, and the controller connect the camera unit and the display panel 100. The display device may be any product or component with display function, such as an electronic paper, a mobile phone, a tablet computer, a television, a monitor, a notebook computer, a digital photo frame, and a navigator.

The display device may further include an input sensor (not shown), and the input sensor may be disposed on the display panel 100. For example, the input sensor may overlap with the display panel 100. The input sensor can detect external input applied from the outside. The external input may be user input. For example, the user's input may include various types of external input, such as a part of the user's body, light, heat, a pen, or pressure. The input sensor may sense the user's input when, for example, a portion of the user's body contacts or approaches the input sensor.

Alternatively, the input sensor may be coupled with the display panel 100 through an adhesive member. In other words, the adhesive member may be located between the input sensor and the display panel 100. The adhesive member may include generic adhesives or stickers. For example, the adhesive member may be a transparent adhesive member such as a pressure sensitive adhesive film (PSA), an optically clear adhesive film (OCA), or an optically clear resin (OCR). The display device may further include a window disposed on the input sensor. The window may include an optically clear insulating material, such as glass or plastic. The window can have a multi-layered structure or a single-layered structure. The window can protect the input sensor and the display panel 100.

In a side-by-side embodiment, the display panel 100 may include a base layer, a circuit layer, a display element layer, and an encapsulation layer. Each of the circuit layer and the display element layer may include a plurality of insulating layers, semiconductor patterns, conductive patterns, signal lines, and the like. The insulating layer, the semiconductor layer, and the conductive layer are provided by methods such as coating and deposition. Thereafter, the insulating layer, the semiconductor layer, and the conductive layer may be selectively patterned by a photolithographic method. The semiconductor patterns, conductive patterns, and signal lines included in the circuit layer and the display element layer are provided by using the above-described method. Thereafter, an encapsulation layer covering the display element layer may be provided. The crack blocking area is provided on the circuit layer, and the ring-shaped detection trace 50 is also provided on the circuit layer. The circular detection trace 50 can be formed by patterning the conductive layer of the crack blocking area dam.

The base layer may include a glass substrate, an organic/inorganic composite substrate, or a synthetic resin film. The synthetic resin film may include thermosetting resin. The base layer may have a multi-layered structure. For example, the base layer may have a three-layered structure of a synthetic resin layer, an adhesive layer, and a synthetic resin layer. The synthetic resin layer may include a polyimide-based resin layer; however, the inventive concept is not particularly limited to the material of the synthetic resin layer. The synthetic resin layer may include at least one of acrylic-based resin, methacrylic-based resin, polyisoprene-based resin, vinyl-based resin, epoxy-based resin, urethane-based resin, cellulose-based resin, a siloxane-based resin, a polyamide-based resin, or a perylene-based resin.

At least one inorganic layer is disposed on the top surface of the base layer. The inorganic layer may include at least one of aluminum oxide, titanium oxide, silicon oxide, silicon oxynitride, zirconium oxide, or hafnium oxide. The inorganic layer may have multiple layers. The multiple layers of inorganic layers may provide barrier and/or buffer layers. In this embodiment, the display panel 100 includes a buffer layer. The buffer layer increases the coupling force between the base layer and the semiconductor pattern. The buffer layer may include a silicon oxide layer and a silicon nitride layer. Here, silicon oxide layers and silicon nitride layers may be alternately stacked on each other. The semiconductor pattern is disposed on the buffer layer. The semiconductor pattern may include polysilicon. However, the inventive concept is not particularly limited thereto. For example, the semiconductor pattern may include amorphous silicon, low temperature polysilicon, or oxide semiconductor.

The semiconductor pattern can have different electrical properties depending on whether it is fully doped, partially doped, or undoped. The semiconductor pattern may include doped regions and non-doped regions. The doped regions may be doped with n-type dopants or p-type dopants. P-type (eg, PMOS) transistors may include doped regions doped with p-type dopants, and n-type (eg, NMOS) transistors may include doped regions doped with n-type dopants. The doped regions may have a greater electrical conductivity than the undoped regions and function as electrodes or signal lines. The undoped region may correspond to the active portion (or channel) of the transistor. In other words, a portion of the semiconductor pattern may be an active portion of a transistor, and another portion of the semiconductor pattern may be a source or drain of the transistor, wherein the another portion of the semiconductor pattern may be connected to an electrode or connected to a signal line.

A first insulating layer may be disposed on the buffer layer. The first insulating layer may commonly overlap the plurality of pixel units 30 and cover the semiconductor pattern. The first insulating layer may be an inorganic layer and/or an organic layer, and has a single-layered structure or a multi-layered structure. The first insulating layer may include at least one of aluminum oxide, titanium oxide, silicon oxide, silicon oxynitride, zirconium oxide, or hafnium oxide. In this embodiment, the first insulating layer may be a single-layered silicon oxide layer. In addition to the first insulating layer, the insulating layer of the circuit layer may be an inorganic layer and/or an organic layer, and has a single-layered structure or a multi-layered structure. Although the inorganic layer may include at least one of the above-mentioned materials, the inventive concept is not particularly limited thereto.

In the display panel 100 provided by the embodiment of the present application, the conductive layer in the crack blocking dam 40 closest to the accommodating hole 11 is configured to form the ring-shaped detection trace 50, and the ring-shaped detection trace 50 is electrically connected to the pixel driving circuits. In this way, when a crack occurs at the accommodating hole 11 in the display area 10, the crack will first impact the ring-shaped detection trace 50, thereby breaking the ring-shaped detection trace 50 and causing abnormal display of the pixel unit 30. That is, the inspector only needs to observe whether the pixel unit 30 connected to the ring-shaped detection trace 50 displays normally to determine whether the crack at the accommodating hole 11 impacts the function of the display panel 100, thereby reducing the difficulty of crack detection. Furthermore, the conductive layer in the crack blocking dam 40 is configured to form the ring-shaped detection trace 50, which can improve the effective utilization rate of the crack blocking dam 40. While achieving the original crack resistance and antistatic ability of the crack blocking dam 40, it can also be used for detecting cracks. Since the ring-shaped detection trace 50 is formed by the conductive layer in the crack blocking dam 40, there is no need to introduce an additional detection circuits, so that the circuit structure of the display panel 100 can be simplified.

In the above embodiments, the descriptions of each embodiment have their own emphasis. The parts that are not described in detail in an embodiment can be referred to the detailed descriptions in other embodiments above, which will not be repeated herein for brevity.

In the description of this application, the terms “first” and “second” are only used for descriptive purposes, and cannot be understood as indicating or implying relative importance or implying the number of indicated technical features. Thus, a feature defined as “first”, “second” may expressly or implicitly include one or more features.

The display panel provided by the embodiments of the present application is described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

What is claimed is:

1. A display panel, comprising:
a display area provided with an accommodating hole;
a pixel unit disposed in the display area, wherein the pixel unit comprises pixel driving circuits arranged in rows and columns;
a crack blocking area defined adjacent to and surrounding the accommodating hole;
a ring-shaped detection trace disposed in the crack blocking area; wherein the ring-shaped detection trace has a ring shape and surrounds the accommodating hole, and the ring-shaped detection trace is configured to provide a signal to at least one of the rows or the columns of the pixel driving circuits.

2. The display panel according to claim 1, wherein the ring-shaped detection trace surrounds the accommodating hole to form a plurality of detection coils, each of the detection coils is non-closed, and adjacent ones of the detection coils are connected in series.

3. The display panel according to claim 2, wherein non-closed positions of at least two of the detection coils are staggered from each other in a radial direction of the accommodating hole.

4. The display panel according to claim 1, wherein the display panel further comprises scan signal lines, EM signal lines, and data signal lines provided in the display area, the data signal lines crisscross the scan signal lines, the EM signal lines are arranged in parallel with the scan signal lines; the data signal lines, the scan signal lines, and the EM signal lines are all connected to the pixel driving circuits; the ring-shaped detection trace is connected in series to at least one of the data signal lines, the scan signal lines, or the EM signal lines.

5. The display panel according to claim 1, wherein the crack blocking area is provided with a crack blocking dam, the crack blocking dam has a conductive layer, and the ring-shaped detection trace is formed by the conductive layer.

6. The display panel according to claim 5, wherein the crack blocking dam comprises a first metal layer, a second metal layer, and a composite metal layer arranged in sequence; an insulating layer is arranged between the first metal layer and the second metal layer and between the second metal layer and the composite metal layer; and the ring-shaped detection trace is formed by one of the first metal layer, the second metal layer, or the composite metal layer.

7. The display panel according to claim 6, wherein the first metal layer and the second metal layer comprise one of molybdenum, silver, titanium, copper, aluminum and alloys thereof; and the composite metal layer comprises titanium/aluminum/titanium.

8. The display panel according to claim 1, wherein the display panel further comprises an encapsulation liquid blocking area defined in the display area, the encapsulation liquid blocking area is defined to surround the accommodating hole, and the encapsulation liquid blocking area is radially defined at a side of the crack blocking area away from the accommodating hole; the encapsulating liquid blocking area is provided with an encapsulating liquid blocking dam, and a size of the encapsulating liquid blocking dam in a direction perpendicular to the display panel is larger than a size of the crack blocking dam in the direction perpendicular to the display panel.

9. The display panel according to claim 2, wherein a distance between adjacent ones of the detection coils is set to be 4 μm to 8 μm.

10. The display panel according to claim 1, wherein the display panel further comprises a frame-shaped detection trace, the frame-shaped detection trace extends along an edge of the display panel, and the frame-shaped detection trace is configured to provide signals to at least one of the rows or the columns of the pixel driving circuits.

11. A display device, comprising a controller, a camera unit, and a display panel, wherein the camera unit is installed in an accommodating hole of the display panel, and the controller is connected to the camera unit and the display panel; and
wherein the display panel comprises:
a display area provided with the accommodating hole;
a pixel unit disposed in the display area, wherein the pixel unit comprises pixel driving circuits arranged in rows and columns;
a crack blocking area defined adjacent to and surrounding the accommodating hole;
a ring-shaped detection trace disposed in the crack blocking area; wherein the ring-shaped detection trace has a ring shape and surrounds the accommodating hole, and the ring-shaped detection trace is configured to provide a signal to at least one of the rows or the columns of the pixel driving circuits.

12. The display device according to claim 11, wherein the ring-shaped detection trace surrounds the accommodating hole to form a plurality of detection coils, each of the detection coils is non-closed, and adjacent ones of the detection coils are connected in series.

13. The display device according to claim 12, wherein non-closed positions of at least two of the detection coils are staggered from each other in a radial direction of the accommodating hole.

14. The display device according to claim 11, wherein the display panel further comprises scan signal lines, EM signal lines, and data signal lines provided in the display area, the data signal lines crisscross the scan signal lines, the EM signal lines are arranged in parallel with the scan signal lines; the data signal lines, the scan signal lines, and the EM signal lines are all connected to the pixel driving circuits; the ring-shaped detection trace is connected in series to at least one of the data signal lines, the scan signal lines, or the EM signal lines.

15. The display device according to claim 11, wherein the crack blocking area is provided with a crack blocking dam, the crack blocking dam has a conductive layer, and the ring-shaped detection trace is formed by the conductive layer.

16. The display device according to claim 15, wherein the crack blocking dam comprises a first metal layer, a second metal layer, and a composite metal layer arranged in sequence; an insulating layer is arranged between the first metal layer and the second metal layer and between the second metal layer and the composite metal layer; and the ring-shaped detection trace is formed by one of the first metal layer, the second metal layer, or the composite metal layer.

17. The display device according to claim 16, wherein the first metal layer and the second metal layer comprise one of molybdenum, silver, titanium, copper, aluminum and alloys thereof; and the composite metal layer comprises titanium/aluminum/titanium.

18. The display device according to claim 11, wherein the display panel further comprises an encapsulation liquid blocking area defined in the display area, the encapsulation liquid blocking area is defined to surround the accommodating hole, and the encapsulation liquid blocking area is radially defined at a side of the crack blocking area away from the accommodating hole; the encapsulating liquid blocking area is provided with an encapsulating liquid blocking dam, and a size of the encapsulating liquid blocking dam in a direction perpendicular to the display panel is larger than a size of the crack blocking dam in the direction perpendicular to the display panel.

19. The display device according to claim 12, wherein a distance between adjacent ones of the detection coils is set to be 4 μm to 8 μm.

20. The display device according to claim 11, wherein the display panel further comprises a frame-shaped detection trace, the frame-shaped detection trace extends along an edge of the display panel, and the frame-shaped detection trace is configured to provide signals to at least one of the rows or the columns of the pixel driving circuits.
